(19) United States
(12) Patent Application Publication
(10) Pub. No.: US 2026/0182407 A1
(43) Pub. Date: Jun. 25, 2026

(54) BGA ELECTRONIC DEVICE WITH GULL WING LEADS

(71) Applicant: Texas Instruments Incorporated, Dallas, TX (US)

(72) Inventors: Francis Glyde Medina, LA UNION (PH); Von Mendoza, Baguio City (PH); Jovenic Esquejo, Baguio City (PH)

(21) Appl. No.: 18/986,867

(22) Filed: Dec. 19, 2024

(51) Int. Cl. H01L 23/498; H01L 21/48; H01L 21/56; H01L 23/00; H01L 23/31

(52) U.S. Cl. CPC H10W 70/65; H10W 70/093; H10W 70/685; H10W 74/016; H10W 74/117; H10W 90/701; H10W 72/07236; H10W 72/07536; H10W 74/15; H10W 90/724; H10W 90/734; H10W 90/754

(57) ABSTRACT

An electronic device includes: a substrate having opposite first and second sides, a first conductive feature on the first side, and a second conductive feature on the second side; a semiconductor die attached to the first side of the substrate; a lead coupled to the first conductive feature and extending outward from a lateral side of the electronic device; and a solder ball coupled to the second conductive feature of the substrate and extending outward from the second side of the substrate.

### BACKGROUND

Modern electronic device manufacturing advances continue to provide higher circuit density and more components in semiconductor dies. However, conventional integrated circuit device types are limited by minimal terminal dimensions and spacing distance specifications that restrict the number of signal connections.

### SUMMARY

In one aspect, an electronic device includes a substrate with opposite sides, a first conductive feature on the first side, and a second conductive feature on the second side, as well as a semiconductor die attached to the first side of the substrate, a lead coupled to the first conductive feature and extending outward from a lateral side of the electronic device, and a solder ball coupled to the second conductive feature of the substrate and extending outward from the second side of the substrate.

In another aspect, a system includes a circuit board having a first conductive pad and a second conductive pad, and an electronic device. The electronic device includes a substrate having opposite first and second sides with a first conductive feature on the first side and a second conductive feature on the second side, and a semiconductor die attached to the first side of the substrate. The electronic device has a lead coupled to the first conductive feature and extending outward from a lateral side of the electronic device, with the lead soldered to the first conductive pad of the circuit board. The electronic device also has a solder ball coupled to the second conductive feature of the substrate and extending outward from the second side of the substrate, with the solder ball soldered to the second conductive feature of the circuit board.

In a further aspect, a method of fabricating an electronic device includes attaching the first side of a substrate to a prospective lead of a lead frame, attaching a semiconductor die to the first side of the substrate, trimming and forming the prospective lead of the lead frame and attaching a solder ball to a second side of the substrate.

### BRIEF DESCRIPTION OF THE DRAWINGS

FIG. 1 is a partial sectional side elevation view of a flip chip quad flat ball grid array (QFBGA) packaged electronic device with gullwing leads on four sides and solder ball connections to a system circuit board taken along line 1-1 of FIGS. 1A-1C.

FIG. 1A is a sectional top plan view of the electronic device taken along line 1A-1A of FIG. 1.

FIG. 1B is a sectional top plan view of the electronic device taken along line 1B-1B of FIG. 1.

FIG. 1C is a bottom view of the electronic device of FIGS. 1-1B.

FIG. 2 is a flow diagram of a method of fabricating an electronic device.

FIGS. 3-10 partial sectional side elevation views of the electronic device of FIGS. 1-1C undergoing fabrication processing according to an implementation of the method of FIG. 2.

FIG. 11 is a bottom view of a flat pack ball grid array packaged electronic device with gullwing leads on two opposite sides and bottom side solder balls.

FIG. 12 is a bottom view of another quad flat ball grid array packaged electronic device with gullwing leads on four sides and bottom side solder balls.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

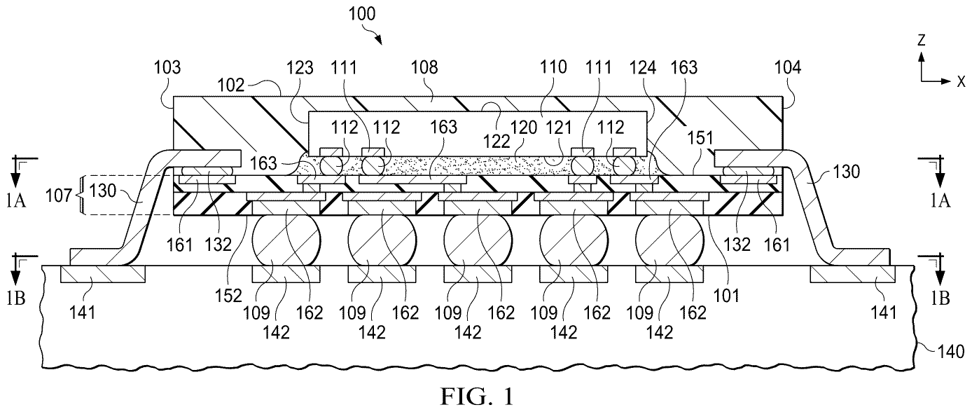

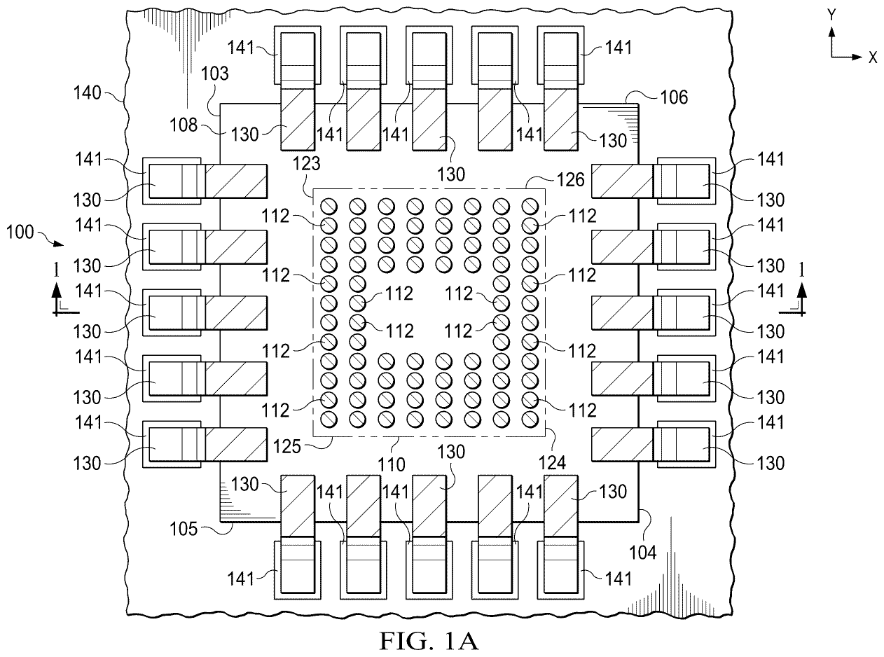

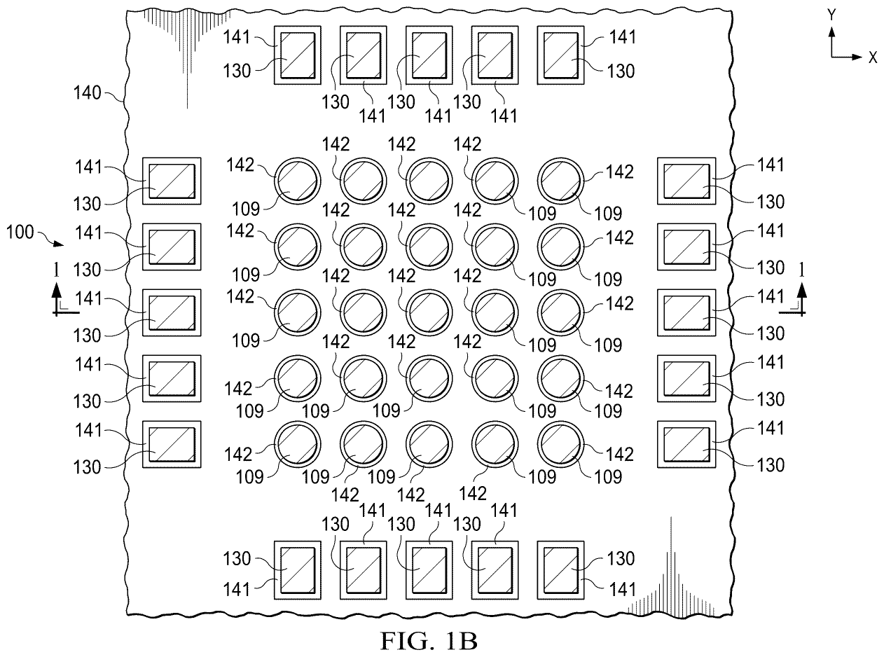

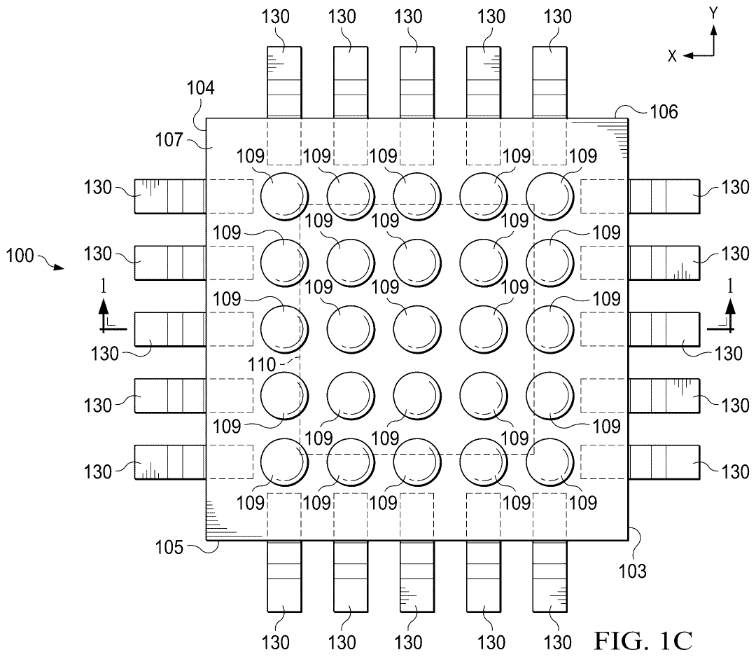

FIGS. 1-1C show an example quad flat ball grid array (QFBGA) electronic device 100 using a leaded substrate 107 with quad flat pack (QFP) leads 130 and ball grid array (BGA) solder balls 109 for enhanced input/output (I/O) connection count. FIG. 1 shows a partial side elevation view of the electronic device 100 with gullwing leads 130 on four sides and solder balls 109 with connections to a system circuit board 140 taken along line 1-1 of FIGS. 1A-1C. FIG. 1A shows a sectional top view of the electronic device 100 taken along line 1A-1A of FIG. 1. FIG. 1B shows a sectional top view taken along line 1B-1B of FIG. 1, and FIG. 1C shows a bottom view of the electronic device 100. The electronic device 100 integrates QFP lead layout with leads 130 on four sides with an interior BGA configuration with rows and columns of solder balls 109 to provide a package that can accommodate high pin count for high density applications.

The electronic device 100 is illustrated in an example position in a three-dimensional space with respective first, second, and third mutually orthogonal directions X, Y (FIGS. 1A-1C) and Z (FIG. 1). The electronic device 100 includes opposite first and second (e.g., bottom and top) sides 101 and 102 (FIG. 1) that are spaced apart from one another along the third direction Z. The electronic device 100 also includes lateral third and fourth sides 103 and 104 (FIGS. 1, 1A and 1C) that are spaced apart from one another along the first direction X, and later fifth and sixth sides 105 and 106 (FIGS. 1A and 1C) that are spaced apart from one another along the second direction Y.

The substrate 107 has conductive features and provides signal and power routing for the electronic device 100 including respective connections from a semiconductor die 110 to the leads 130 and the solder balls 109. The substrate 107 extends along the first side 101 of the electronic device 100. In one example, the substrate 107 is a multilevel package substrate that can also be referred to a routable lead frame (RLF) or a FCCSP embedded trace substrate (ETS) or cored substrate with prepreg or other suitable dielectric layers. The example substrate 107 is a two level stacked structure with dielectric layers and patterned conductive metal features including trace layer features and conductive metal via features. In other examples, any suitable number of two or more levels can be used with trace and/or via layer features such as multilayer ETS or cored substrate.

The illustrated example is a hybrid ball grid array (BGA) package with solder ball terminals 109 connected to bottom side trace or via features of the substrate 107 to facilitate soldering to a host circuit board 140 as shown in FIG. 1. The substrate 107 and the solder ball terminals 109 provide mechanical and electrical connection of the semiconductor die 110 to conductive features 142 of the circuit board 140. The substrate trace and via routings provide desired electrical connections between the components of the device 100 and the solder ball leads 109. As shown in FIG. 1, the substrate 107 has opposite first and second (e.g., top and bottom) sides 151 and 152, with first conductive features 161 on peripheral portions of the first side 151 that are connected to respective ones of the leads 130. The substrate 107 also includes second conductive features 162 on the second side 152 that are connected to respective ones of the solder balls 109.

The semiconductor die 110 has opposite first and second sides 121 and 122 (e.g., respective bottom and top sides in the illustrated position of FIG. 1). The first side 121 is the die front side and the second side 122 is the die back side. The substrate 107 also includes third conductive features 163 on an interior portion of the first side 151 that are configured for flip-chip soldering of the semiconductor die 110 to attach the semiconductor die 110 to the first side 151 of the substrate 107. The semiconductor die 110 has conductive features 111, such as conductive metal terminals that are electrically coupled to the third conductive feature 163 of the substrate 107. In the illustrated example, the semiconductor die 110 has conductive metal terminals 111 (e.g., copper pillars or bumps in FIG. 1) that are located along the first side 121 and attached and directly electrically coupled by solder 112 to respective first conductive features along the top side of the substrate 107. The conductive metal terminals 111 in one example extend outward (e.g., downward) from the first side 121 of the semiconductor die 110 along the third direction Z (FIG. 1). The semiconductor die 110 also has respective lateral third and fourth sides 123 and 124 (FIGS. 1 and 1A) and lateral fifth and sixth sides 125 and 126 (FIG. 1A).

Other electronic components (not shown) can be included, such as further semiconductor dies, passive or active surface mount components (e.g., resistors, capacitors, inductors, transformers, diodes, transistors, etc.) or combinations thereof, and which can be attached (e.g., soldered) to corresponding conductive features on the top side of the substrate 107. A package structure 108 (e.g., a molded plastic structure as shown in FIGS. 1 and 1A) extends on a portion of the top side of the substrate 107 and may extend underneath the bottom side 121 of the semiconductor die 110 in the flip-chip attached implementation as shown in FIG. 1.

The illustrated flip-chip example includes underfill material 120 (e.g., electrical insulator) that extends between the bottom side of the semiconductor die 110 and the top side 151 of the substrate 107 and laterally between the terminals 111 and solder connections 112. In another example, the semiconductor die 110 can be attached to the top side 151 of the substrate 107 using die attach film or other suitable adhesive (not shown) and top side bond wire connections can electrically connect the semiconductor die 110 to conductive features of the substrate 107 and/or to one or more of the leads 130. The package structure 108 extends from the top side 151 of the substrate 107 to the second side 102 of the electronic device 100. The package structure 108 encloses interior portions of the leads 109, the semiconductor die 110 and a portion of the first side 151 of the substrate 107.

As shown in FIG. 1, the leads 130 are individually coupled to respective ones of the first conductive features 161. In the illustrated example, the leads 130 are soldered to respective first conductive features 161 of the substrate 107 by solder 132 as shown in FIG. 1. In another implementation, the leads 130 can be attached to the respective first conductive features 161 using a conductive adhesive (not shown), or other suitable material that forms electrical and mechanical connection between the individual leads 130 and a respective one of the first conductive features 161 of the substrate 107. The leads 130 in this example extend outward from a respective one of the lateral sides 103-106 of the electronic device 100. The solder balls 109 are coupled to the respective second conductive features 162 of the substrate 107 and extend outward (e.g., downward) from the second side 152 of the substrate 107.

As shown in FIGS. 1A-1C, the example electronic device 100 is a hybrid quad flat pack (QFP) ball grid array (BGA) configuration with instances of the leads 130 extending outward from all four lateral sides 103, 104, 105 and 106 of the electronic device 100, and with instances of the solder ball 109 arranged in rows and orthogonal columns along the respective first and second directions X and Y. In this example, the leads 130 are gullwing leads. In other examples, different lead types can be used having different shapes or forms (not shown).

The electronic device 100 is shown in FIGS. 1-1B installed on a system circuit board 140 having first conductive pads 141 and second conductive pads 142 (e.g., copper, aluminum, or other suitable conductive metal) along a top side of the circuit board 140. As best shown in FIG. 1B, the layout of the circuit board 140 provides an array with rows and columns of the second conductive pads 142 that correspond with the locations of the solder balls 109 of the electronic device 100 along the first and second directions X and Y. In this example, moreover, the first conductive pads 141 are arranged in rows laterally outward of the array of solder balls 109 with suitable lateral spacing to accommodate the gullwing shaped leads 130.

As further shown in FIG. 1, moreover, the gullwing leads 130 extend downward and laterally outward to provide lead end shapes with an approximately co-planar bottom surfaces that extend in a plane that intersects the solder balls 109. This provides a structure configured to be soldered to the conductive pads 141 and 142 along the generally planar top side of the circuit board 140. In one example, solder paste can be formed (e.g., silkscreened, dispensed, printed, etc.) on the tops of the first conductive pads 141 of the circuit board 140, followed by attachment of the electronic device 100 with the leads 130 engaging the solder paste above the corresponding first conductive pad 140 and with the solder balls 109 engaging the top sides of the corresponding second conductive pads 142, followed by heating to reflow the solder paste and the solder of the solder balls 109 to form soldered connections to the circuit board 140.

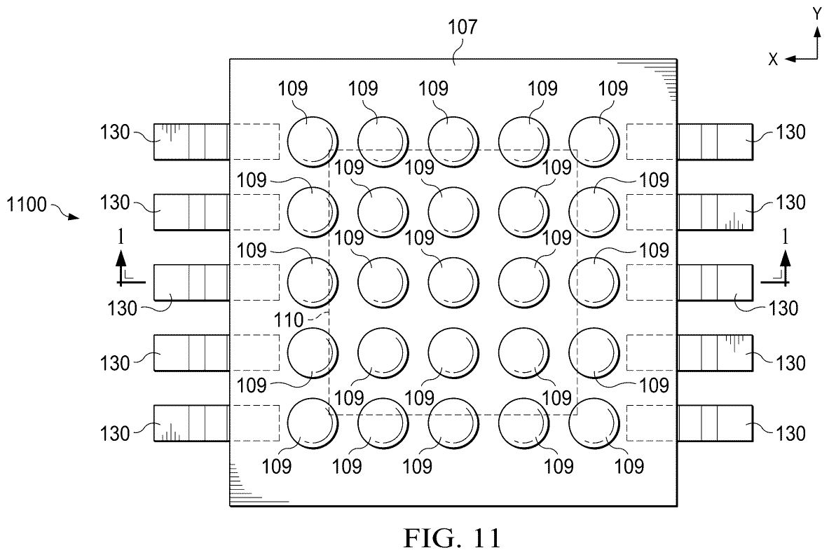

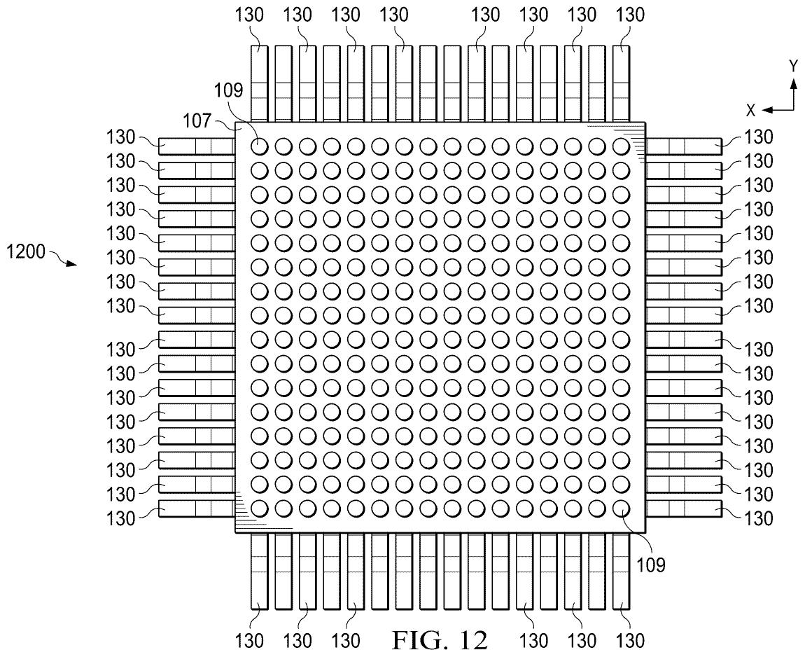

Further non-limiting examples are shown in FIGS. 11 and 12 below, including a hybrid dual flat pack BGA example with gullwing leads on two opposite sides (FIG. 11) and another higher I/O density example hybrid QFP/BGA implementation (FIG. 12). The provision of one or more solder balls in an interior portion along a bottom side of the substrate 107 along with two or more outlying rows of leads 130 extending from an attached to the substrate 107 facilitates increased circuit density within a given host system. The electronic device 100 and the further examples of FIGS. 11 and 12 provide more interconnections than conventional BGA device implementations, and higher connection count compared to conventional flatpack designs of a similar size. In one example, a 7 mm×7 mm package can accommodate four rows of 16 gullwing leads 130 with a 0.4 mm pitch in addition to 225 solder balls 109 with a 0.4 mm pitch for a total of I/O count of 289.

These examples and other variants can be manufactured using cost effective and well-developed fabrication equipment and techniques. In addition, host circuit boards can be configured to accommodate the hybrid interconnections with conductive pads for both the leads 130 and the solder balls 109. The example electronic device 100 employees flip-chip attachment of the semiconductor die 110 to the top side 151 of the substrate 107, with the substrate 107 providing interconnection routing for the terminals 111 of the semiconductor die 110 as well as the leads 130 and the solder balls 109. In another implementation, wire bonding can be used for one or more interconnections alone or in combination with flip-chip attachment. Other alternate implementations can provide integration of further electronic components in the electronic device 100, for example, attachment and interconnection of additional dies, surface mount components, etc. (not shown).

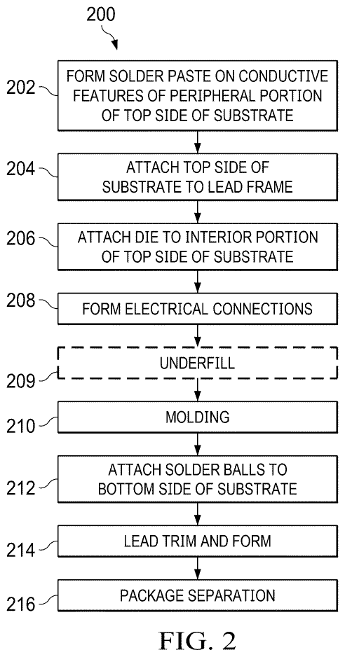

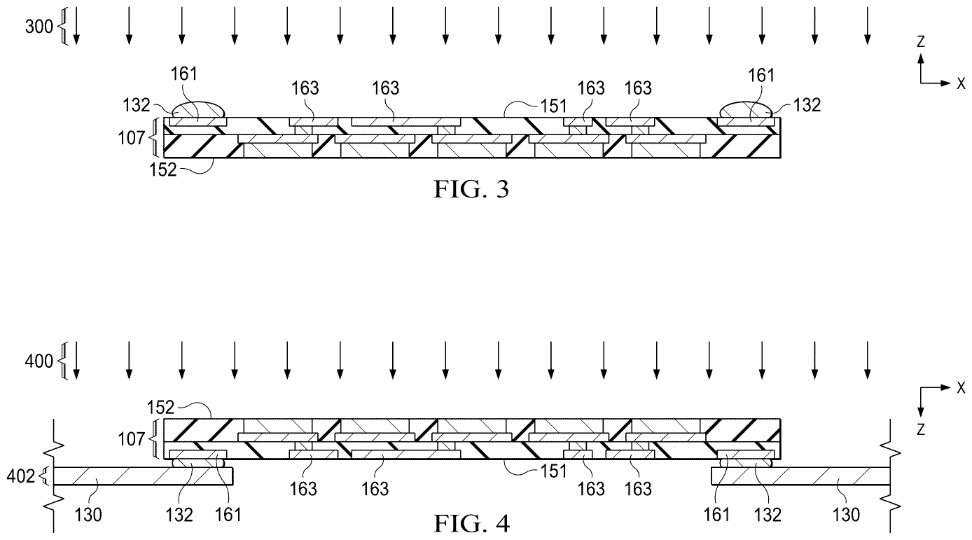

Referring now to FIGS. 2-10, FIG. 2 shows a method 200 of fabricating an electronic device, and FIGS. 3-10 illustrate the example electronic device 100 undergoing fabrication processing according to an implementation of the method 200. The method 200 begins with attachment of the substrate 107 to a lead frame at 202 and 204 in FIG. 2. The illustrated example includes a previously formed multilevel package substrate 107 that has been singulated or separated from a starting substrate panel array with multiple unit areas individually corresponding to an instance of the described multilevel package substrate 107. This example includes attachment of a separated substrate 107 in each unit area of a starting lead frame panel array having multiple unit areas individually corresponding to instances of a finished packaged electronic device 100 as described above. In another possible implementation, the substrate panel array can be attached to a starting lead frame panel array and various packaging processing can be performed prior to separation of individual unit areas of the substrate panel array and the lead frame panel array.

At 202 in FIG. 2, the example method 200 includes forming solder paste (or conductive adhesive) on conductive features of a peripheral portion of a top side 151 of the substrate 107. FIG. 3 shows one example, in which a solder formation process 300 is performed that forms solder 132 on select portions of the first side 151 of the substrate 107 that correspond to prospective attachment locations of the leads 130 of the lead frame panel array, such as portions of the first conductive features 161 along the first side 151 of the substrate 107. Any suitable solder paste or adhesive formation processing and equipment can be used, such as silk screening, printing, etc. In another example, solder 132 (or conductive adhesive) can alternatively or in combination be formed on the prospective attachment location of the leads 130 of the lead frame panel array prior to engaging the substrate 107 with the lead frame in each unit area of the panel array structure.

At 204 in FIG. 2, the method 200 continues with attaching the top side 151 of the substrate 107 to the lead frame. FIG. 4 shows one example, in which a substrate attachment process 400 is performed that attaches an instance of the substrate 107 in an illustrated unit area of a lead frame panel array 402, also referred to as a lead frame. In one implementation, the lead frame panel array 402 includes rows and columns of unit areas, one of which is shown in FIG. 4. The process 400 attaches the first side 151 of the substrate 107 to prospective leads 130 of in the illustrated unit area of the lead frame 402. In one example, the process 400 includes similarly attaching further instances of the substrate 107 to prospective leads 130 in further unit areas (not shown) of the lead frame 402. The process 400 in one example includes soldering a portion of the first side 151 of the substrate 107 to a portion of the prospective lead 130 of the lead frame 402, for example, by thermal processing to reflow the previously applied solder paste 132 and form solder connections between the first conductive features 161 of the substrate 107 and the prospective leads 130.

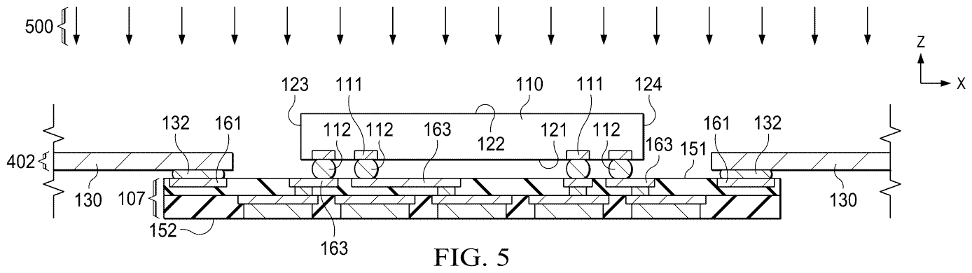

The method 200 continues at 206 in FIG. 2 with die attach processing of the individual unit areas of the lead frame panel array structure 402. FIG. 5 shows one example, in which a die attach process 500 is performed that attaches an instance of the semiconductor die 110 to the first side 151 of the substrate 107. The illustrated example includes flip chip attachment of the semiconductor die 110 to the first side 151 of the substrate 107, with the solder 112 of the die terminals 111 engaging the corresponding respective third conductive features 163 of the substrate 107. In another example, the attachment at 206 can include dispensing die attach film or other adhesive (not shown) on a portion of the first side 151 of the substrate 107 and attachment of the semiconductor die (e.g., using automated pick and place equipment, not shown) on the previously formed adhesive in the unit area of the lead frame 402.

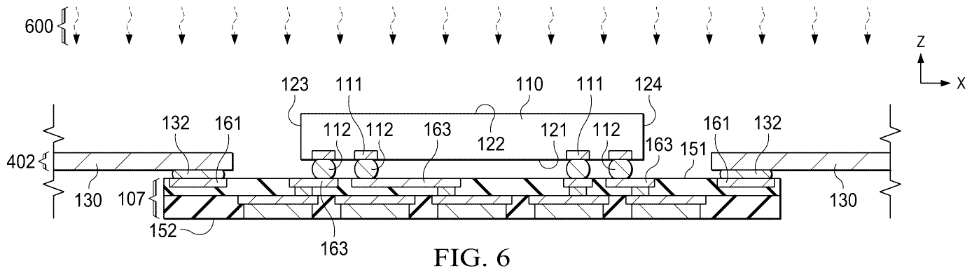

The method 200 continues with electrical connection formation at 208 in FIG. 2. FIG. 6 shows one example, in which a thermal reflow process 600 is performed that forms or completes electrical connections between the conductive metal terminals 111 of the semiconductor die 110 and the corresponding third conductive features 163 of the substrate 107. In the illustrated example, the thermal process 600 reflows the solder 112 to solder the conductive terminals 111 of the semiconductor die 110 to the corresponding third conductive features 163 on the first side 151 of the substrate 107. In another example, where the semiconductor die 110 was attached (e.g., at 206 in FIG. 2) using die attach adhesive, the electrical connection at 208 can include forming bond wires (not shown) to electrically connect conductive metal features (e.g., bond pads) of the semiconductor die 110 to corresponding conductive features (not shown) of the substrate 107 and/or to connect bond pads of the semiconductor die 110 to corresponding ones of the leads 130.

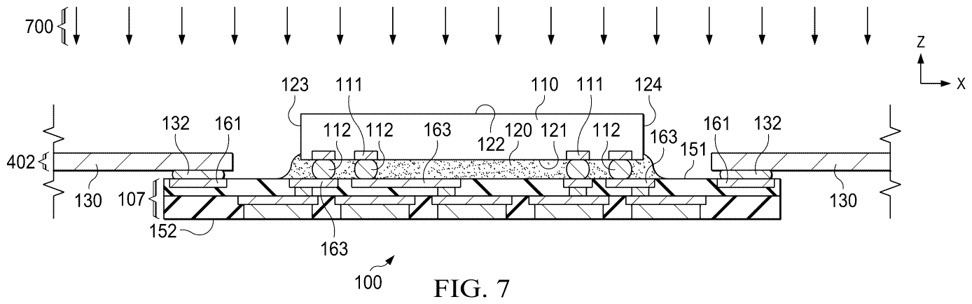

The method 200 in one example continues at 209 in FIG. 2 with optional underfill formation. FIG. 7 shows one example, in which an underfill process 700 is performed that forms the underfill material 120 between the bottom side of the semiconductor die 110 and the top side 151 of the substrate 107 and laterally between the terminals 111 and solder connections 112. In another implementation, for example, where the semiconductor die 110 is not flip chip soldered to the substrate 107, the underfill processing at 209 in FIG. 2 can be omitted.

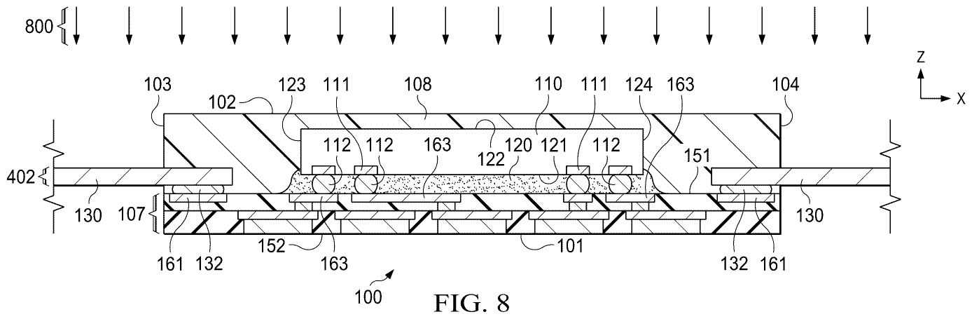

The method 200 continues at 210 in FIG. 2 with package molding. FIG. 8 shows one example, in which a molding process 800 is performed using a mold (not shown). The process 800 forms the molded package structure 108 to enclose the semiconductor die 110, portions of the top side 151 of the substrate 107 and a portion of the prospective leads 130 of the lead frame 402. In one implementation, a single mold cavity can be used to create a molded package structure 108 that extends across multiple unit areas of the lead frame 402. In other implementations, the mold includes individual mold cavities for each unit area or groups of fewer than all unit areas can be included within a shared mold cavity (not shown).

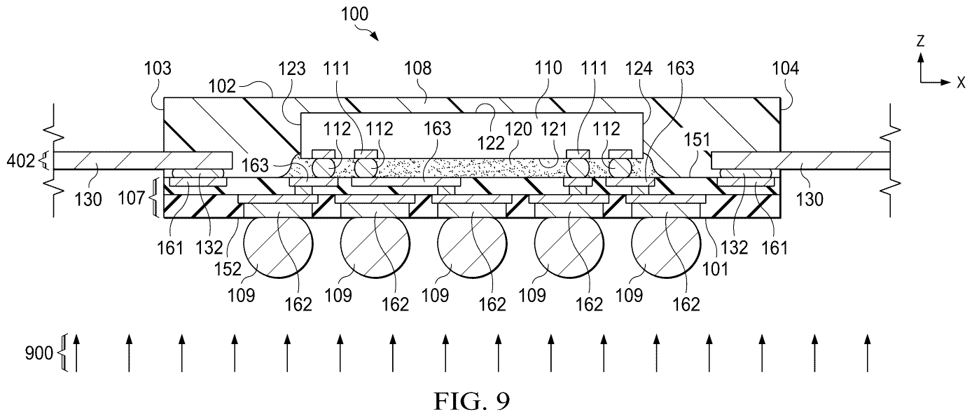

The method 200 continues at 212 in FIG. 2 with solder ball attach processing. FIG. 9 shows one example, in which a ball attach process 900 is performed, for example, using automated ball attach or ball drop equipment (not shown). The ball attach process 900 attaches the solder balls 109 to corresponding respective locations on the second side 152 of the substrate 107, for example, on the corresponding second conductive features 162 of the substrate 107.

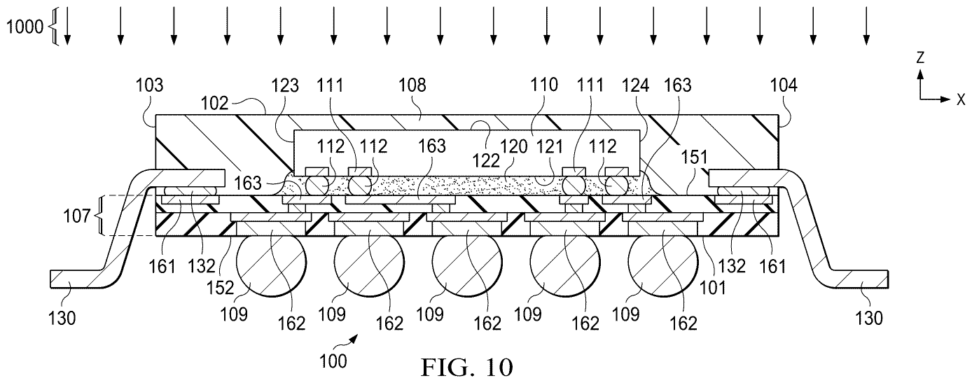

The method 200 in one example includes lead trimming and forming at 214 in FIG. 2. FIG. 10 shows one example, in which a lead trimming and forming process 1000 is performed that trims and forms the prospective leads 130 in each unit area of the lead frame 402. The illustrated example trims exposed portions of the lead frame to separate leads 130 of adjacent unit areas, and then forms the trimmed leads 130 into the gullwing shape illustrated in FIGS. 1-1C and 10. In other implementations, alternate forming operations can be used to form leads having different shapes (not shown).

In one implementation, the method 200 proceeds with package separation at 216 in FIG. 2 to separate individual packaged electronic devices 100 from the starting lead frame panel array structure 402. The package separation at 216 in one example includes laser or saw cutting along scribe streets between adjacent rows and columns of unit areas of the starting lead frame panel array structure, for example, to cut through tie bars and other temporary support structures (not shown) of the starting lead frame 402.

FIG. 11 shows a bottom view of another example flat pack ball grid array packaged electronic device 1100 with gullwing leads on two opposite sides and bottom side solder balls. The electronic device 1100 includes structures and features as generally illustrated above in connection with FIG. 1 but differs from the example electronic device 100 and having gullwing leads 130 only on two opposite lateral sides.

FIG. 12 shows a bottom view of another example quad flat ball grid array (QFPBGA) packaged electronic device 1200 with gullwing leads on four sides and bottom side solder balls. The electronic device 1200 includes similarly numbered structures and features, with other details generally corresponding to the electronic device 100 described above in connection with FIGS. 1-1C. This example provides a high I/O count implementation with 320 interconnections including 256 solder balls 109 and 64 gullwing leads 130.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a substrate having opposite first and second sides, a first conductive feature on the first side, and a second conductive feature on the second side;
a semiconductor die attached to the first side of the substrate;
a lead coupled to the first conductive feature and extending outward from a lateral side of the electronic device; and
a solder ball coupled to the second conductive feature of the substrate and extending outward from the second side of the substrate.

2. The electronic device of claim 1, wherein:
the substrate has a third conductive features on the first side; and
the semiconductor die has a conductive feature electrically coupled to the third conductive feature of the substrate.

3. The electronic device of claim 2, wherein the conductive feature of the semiconductor die is soldered to the third conductive feature on the first side of the substrate.

4. The electronic device of claim 2, wherein the conductive feature of the semiconductor die is wire bonded to the third conductive feature on the first side of the substrate.

5. The electronic device of claim 1, comprising instances of the lead extending outward from four lateral sides of the electronic device.

6. The electronic device of claim 1, comprising instances of the solder ball arranged in rows and orthogonal columns.

7. The electronic device of claim 1, wherein the substrate has multiple levels.

8. The electronic device of claim 1, wherein the lead is a gullwing lead.

9. The electronic device of claim 1, wherein the lead and the solder ball are configured to be soldered to a planar side of a circuit board.

10. The electronic device of claim 1, wherein the lead is soldered to the first conductive feature of the substrate.

11. The electronic device of claim 1, further comprising a package structure that encloses a portion of the lead, the semiconductor die and a portion of the first side of the substrate.

12. A system, comprising:
a circuit board having a first conductive pad and a second conductive pad; and
an electronic device, including:
a substrate having opposite first and second sides, a first conductive feature on the first side, and a second conductive feature on the second side;
a semiconductor die attached to the first side of the substrate;
a lead coupled to the first conductive feature and extending outward from a lateral side of the electronic device, the lead soldered to the first conductive pad of the circuit board; and
a solder ball coupled to the second conductive feature of the substrate and extending outward from the second side of the substrate, the solder ball soldered to the second conductive feature of the circuit board.

13. The system of claim 12, comprising instances of the lead extending outward from four lateral sides of the electronic device and soldered to respective instances of the first conductive pad of the circuit board.

14. The system of claim 12, the electronic device comprising instances of the solder ball arranged in rows and orthogonal columns and extending outward from the second side of the substrate, the individual instances of the solder ball coupled to a respective instance of the second conductive feature of the substrate.

15. The system of claim 12, wherein the lead is soldered to the first conductive feature of the substrate.

16. A method of fabricating an electronic device, the method comprising:
attaching a first side of a substrate to a prospective lead of a lead frame;
attaching a semiconductor die to the first side of the substrate;
trimming and forming the prospective lead of the lead frame; and
attaching a solder ball to a second side of the substrate.

17. The method of claim 16, wherein attaching the first side of the substrate to the prospective lead of the lead frame includes soldering the first side of the substrate to the prospective lead of the lead frame.

18. The method of claim 16, wherein attaching a semiconductor die to the first side of the substrate includes soldering a conductive feature of the semiconductor die to a conductive feature on the first side of the substrate.

19. The method of claim 16, comprising forming a bond wire to connect a conductive feature of the semiconductor die to a conductive feature on the first side of the substrate.

20. The method of claim 16, comprising enclosing the semiconductor die and a portion of the prospective lead of the lead frame in a package structure.
